(19) United States
(12) Patent Application Publication
(10) Pub. No.: US 2023/0064343 A1
(43) Pub. Date: Mar. 2, 2023

(54) DISCHARGE DETECTION APPARATUS AND CHARGED PARTICLE BEAM IRRADIATION APPARATUS

(71) Applicant: NuFlare Technology, Inc., Yokohama-shi (JP)

(72) Inventors: Tatsuya MUROFUSHI, Gotemba-sh (JP); Yoshiro YAMANAKA, Yokohama-shi (JP); Hiroki HAYAKAWA, Yokohama-shi (JP)

(73) Assignee: NuFlare Technology, Inc., Yokohama-shi (JP)

(21) Appl. No.: 17/823,558

(22) Filed: Aug. 31, 2022

(30) Foreign Application Priority Data
Aug. 31, 2021 (JP) 2021-141333

(51) Int. Cl. H01J 37/244; H01J 37/32

(52) U.S. Cl. CPC H01J 37/244; H01J 37/3211; H01J 37/32981

(57) ABSTRACT

A discharge detection apparatus includes a vacuum container, a conductive installation member in the vacuum container, the installation member being connected to the vacuum container so as to be retained by the vacuum container; a conductive antenna in the vacuum container; and a retainer comprising a material having a specific resistance of 1×10⁵ to 1×10¹¹ (Ω·cm), the retainer retaining the antenna with respect to the installation member without a contact between the installation member and the antenna, by means of a screw located through an inside of the antenna and an inside of the retainer.

### CROSS-REFERENCE TO RELATED APPLICATIONS

This application is based upon and claims the benefit of priority from Japanese Patent Application No. 2021-141333, filed Aug. 31, 2021, the entire contents of which are incorporated herein by reference.

### FIELD

The embodiments described herein relate generally to a discharge detection apparatus and a charged particle beam irradiation apparatus.

### BACKGROUND

Lithography technology is used in process for forming wiring patterns for semiconductor devices, and plays an extremely important role in the manufacturing process of semiconductor devices. In recent years, a line width of wiring required for semiconductor devices has been made finer year by year with the greater implementation of large scale integration (LSI).

A high-precision original image pattern (also referred to as a reticle or a mask) is used to form a wiring pattern with a line width made fine. The production of a high-precision original image pattern uses, for example, an electron beam drawing technique having excellent resolution. As an apparatus for producing an original image pattern using the electron beam drawing technique, an electron beam drawing apparatus of a variable beam shaping type is known.

The electron beam drawing apparatus variously shapes an electron beam by a variable beam shaping method, and irradiates a sample with the shaped electron beam. By this irradiation, drawing is performed on the sample and an original image pattern is thus produced.

Here, the electron beam drawing apparatus contains insulating components in its housing, and may also contain unintended insulating objects such as contamination and/or dust. These insulating objects, etc. are often charged and discharged by scattered electrons. The discharge causes a momentary electric field variation in the housing, which can cause fluctuations in the path of electron beams. The insulating objects are locally carbonized due to the heat from the discharge, and such carbonized insulating objects tend to shorten the discharge path (creeping distance) so as to gradually increase the frequency of discharges. Fluctuations in the path of electron beams during drawing operations could result in problems such as an error in drawing patterns.

In order to detect discharges as discussed above, a discharge detection apparatus is employed. The discharge detection apparatus is capable of detecting discharges even during the period where the frequency of discharges is relatively low. Once a discharge is detected, measures such as replacement of components can be taken (cf., for example, Jpn. Pat. Appln. KOKAI Publication No. 2008-311364, Jpn. Pat. Appln. KOKAI Publication No. 2007-335786, and Jpn. Pat. Appln. KOKAI Publication No. 2004-288849).

The discharge detection apparatus includes, for example, an antenna constituted by a metal plate or the like, and an insulating member for retaining the antenna within the housing while electrically insulating the antenna from the housing. The electric field variation caused by a discharge affects the electrical potential of the antenna. Electric signals according to the electrical potential of the antenna are acquired by, for example, a waveform measurement instrument located outside the housing.

Note that the insulating member itself can be charged and discharged by scattered electrons and become a cause of problems such as a pattern error as mentioned above. One way to address such discharges may be the use of a configuration in which the insulating member is covered with a conductor having an electrical connection to the housing. This configuration, however, does not completely cover the insulating member with the conductor since the electrical isolation of the antenna from the housing must be secured. As such, the configuration cannot completely prevent the discharges caused by the insulating member.

### SUMMARY

The present invention has been made in view of the above circumstances, and an object of the present invention is to provide a discharge detection apparatus and a charged particle beam irradiation apparatus that can reduce the frequency of discharges caused by the retaining member for retaining the antenna.

A discharge detection apparatus includes a vacuum container, a conductive installation member in the vacuum container, the installation member being connected to the vacuum container so as to be retained by the vacuum container; a conductive antenna in the vacuum container; and a retainer comprising a material having a specific resistance of 1×10⁵ to 1×10¹¹ (Ω·cm), the retainer retaining the antenna with respect to the installation member without a contact between the installation member and the antenna, by means of a screw located through an inside of the antenna and an inside of the retainer.

### BRIEF DESCRIPTION OF THE DRAWINGS

FIG. 1 is a configuration view schematically showing an exemplary configuration of an electron beam drawing apparatus according to a first embodiment.

FIG. 2 is a configuration view schematically showing an exemplary configuration of a discharge detecting unit of the electron beam drawing apparatus according to the first embodiment.

FIG. 3 is a configuration view schematically showing another exemplary configuration of the discharge detecting unit of the electron beam drawing apparatus according to the first embodiment.

FIG. 4 shows an exemplary sectional structure of an insulating bushing of the electron beam drawing apparatus according to the first embodiment.

FIG. 5 is an exemplary graph on which voltage data is plotted.

FIG. 6 is a diagram for schematically illustrating movements of electrons caught by the insulating bushing of the electron beam drawing apparatus according to the first embodiment.

FIG. 7 is an exemplary graph on which a sum of the number of discharges detected by the discharge detecting unit of the electron beam drawing apparatus according to the first embodiment is plotted with respect to a time axis.

### DETAILED DESCRIPTION

Hereinafter, embodiments will be described with reference to the drawings. In the following description, components having the same function and configuration will be assigned a common reference symbol. When a plurality of components assigned a common reference symbol are distinguished from each other, suffixes are added after the common reference symbol for the distinction. When the components need not be particularly distinguished from one another, the components are assigned only the common reference symbol without suffixes. The embodiments to be described below are mere exemplification of an apparatus and a method for embodying a technical idea, and the shape, configuration, and arrangement of each component are not limited to the ones described below.

Each function block can be implemented in the form of hardware, software, or a combination thereof. The function blocks are not necessarily separated from one another as described below. For example, some of the functions may be implemented by a function block other than the function blocks to be described as an example. In addition, the function blocks to be described as an example may be further divided into functional sub-blocks. The names of the function blocks and components in the following description are assigned for convenience, and do not limit the configurations or operations of the function blocks and components.

When a numerical value appears in the following description, significant digits or significant figures can be taken into consideration for interpreting the numerical value.

### First Embodiment

Hereinafter, an electron beam drawing apparatus will be described as a non-limiting example of a charged particle beam irradiation apparatus according to the embodiment. Note, however, that the embodiment is not limited to this. For example, the disclosure herein may also be applied to other apparatuses using charged particle beams such as electron beams and ion beams. Examples of such apparatuses include a focused ion beam drawing apparatus, an inspection apparatus for original image patterns, an electron microscope, a field emission ion microscope, and so on. The apparatuses may utilize not only a single beam technique but also multi-beam technique.

### Exemplary Configuration

### (1) Electron Beam Drawing Apparatus

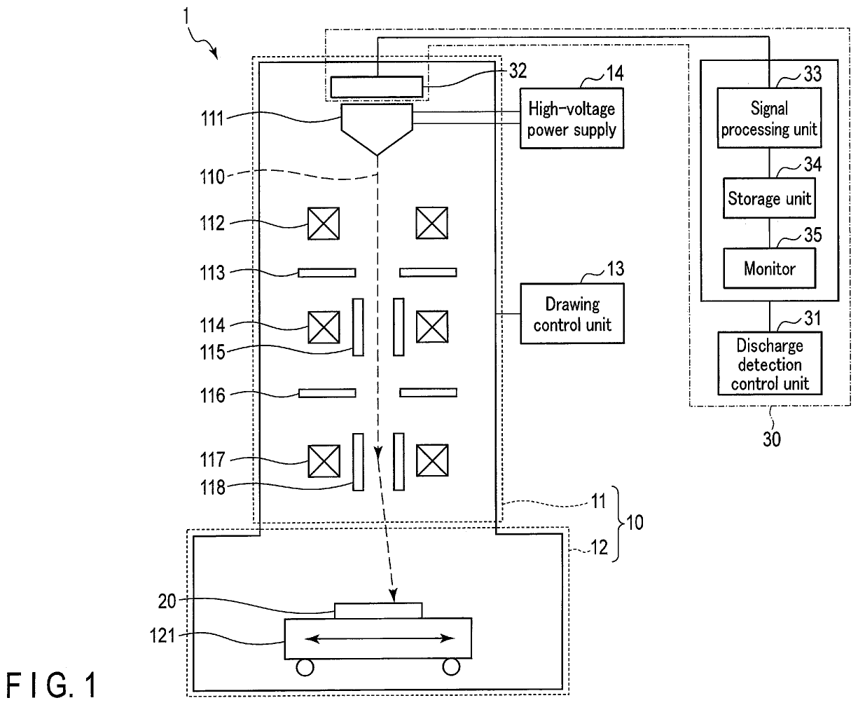

FIG. 1 is a configuration view schematically showing an exemplary configuration of an electron beam drawing apparatus 1 according to the first embodiment. FIG. 1 sets forth the configuration of the electron beam drawing apparatus 1 by way of example only and does not intend a limitation. For example, the electron beam drawing apparatus 1 may include constituent elements or components other than those illustrated in the figure which an electron beam drawing apparatus may generally include. Further, the electron beam drawing apparatus 1 may include each component in an arrangement different from that illustrated in the figure.

The electron beam drawing apparatus 1 includes, for example, a drawing unit 10, a drawing control unit 13, and a high-voltage power supply 14. The drawing unit 10 includes a housing constituted by an electron lens barrel 11 and a drawing chamber 12.

The drawing unit 10 includes, inside the electron lens barrel 11, components such as an electron gun 111, an illumination lens 112, a first aperture member 113, a projection lens 114, a first deflector 115, a second aperture member 116, an objective lens 117, and a second deflector 118. The drawing unit 10 includes, inside the drawing chamber 12, components such as a stage 121. A sample 20 can be fixed onto the stage 121. The inside of the electron lens barrel 11 and the inside of the drawing chamber 12 are vacuumed by a vacuum pump (not shown in the figure) and maintained at a pressure state sufficiently lower than the atmosphere, namely, at a so-called vacuum state. The electron beam drawing apparatus 1 uses an electron beam 110 emitted from the electron gun 101 to perform drawing on the sample 20 fixed onto the stage 121.

For the following description, two directions crossing each other at, for example, right angles and parallel to one surface of the stage 121, where the sample 21 is fixed, are defined as an X direction and a Y direction. A direction passing through this surface and extending toward the electron gun 111 is defined as a Z direction. The description will assume the Z direction to be orthogonal to both the X direction and the Y direction, but this is not a limitation. The description will also assume the Z direction to represent “up”, “above”, or the like, and the direction opposite to the Z direction to represent “down”, “below”, or the like; however, such representation is merely for convenience and not associated with, for example, the direction of gravity.

The high-voltage power supply 14 is connected to the electron gun 111 and applies a high voltage to the electron gun 111. The electron gun 101 emits the electron beam 100 according to the application of high voltage. The drawing control unit 13 controls voltages applied to respective electrodes included in the first deflector 115 and the second deflector 118, so as to control electric fields in the regions through which the electron beam 110 travels.

The first aperture member 113 and the second aperture member 116 are disposed, in this order from above, between the electron gun 111 and the stage 121.

The illumination lens 112 is disposed, for example, above the first aperture member 113. The first aperture member 113 includes an opening which is, for example, rectangular in shape. The illumination lens 112 causes the electron beam 110 to illuminate the entire first aperture member 113. The electron beam 110, by passing through the first aperture member 113, is shaped into a profile that corresponds to the opening, for example, a rectangular profile.

The projection lens 114 and the first deflector 115 are provided, for example, between the first aperture member 113 and the second aperture member 116. The second aperture member 116 includes an opening. The projection lens 114 causes the electron beam 110 to be projected onto a plane that includes the top surface of the second aperture member 116 by, for example, adjusting the focal point of the electron beam 110 that has passed through the opening of the first aperture member 113. The first deflector 115 includes multiple electrodes and changes the electric field in the region sandwiched or surrounded by these electrodes, so that it can change the path of the electron beam 110 traveling through this region. The first deflector 115, by changing the path in this manner, controls the projection position of the electron beam 110 on the plane that includes the top surface of the second aperture member 116. Among the portions of the electron beam 110 projected onto this plane, the portion projected onto the region of the opening of the second aperture member 116 passes through the second aperture member 116. With this control, the shape and dimensions of the electron beam 110 passing through the second aperture member 116 can be changed.

The objective lens 117 and the second deflector 118 are provided, for example, between the second aperture member 116 and the stage 121. The stage 121 can continuously move, for example, in the X direction and the Y direction. In one example, the objective lens 117 adjusts the focal point of the electron beam 110 that has passed through the opening of the second aperture member 116. The second deflector 118 includes multiple electrodes and changes the electric field in the region sandwiched or surrounded by these electrodes, so that it can change the path of the electron beam 110 traveling through this region. The second deflector 118, by changing the path in this manner, controls the irradiation position of the electron beam 110 on the sample 20 placed on the continuously moving stage 121.

In the drawing unit 10, insulating objects may be charged and discharged by scattered electrons from the electron beam 110. In order to detect such discharges, the electron beam drawing apparatus 1 includes a discharge detecting unit 30. The following description may also refer to the discharge detecting unit 30 as a discharge detection apparatus.

The discharge detecting unit 30 includes a discharge detection control unit 31, a sensor 32, a signal processing unit 33, a storage unit 34, and a monitor 35. The discharge detection control unit 31 conducts controls for the detection of discharges.

The sensor 32 is used as an antenna or an electrode. In the context of this disclosure, an antenna refers to an element or a device which is constituted by a conductive substance or material such as metal, and which is capable of capturing a variation in one or more of electromagnetic waves, electric fields, and/or magnetic fields in the air, converting the captured variation into a voltage signal or a current signal, and outputting the signal. An antenna of this type allows for the acquisition of signals associated with discharges. The disclosure herein assumes that the sensor 32 is constituted by a metal plate; however, the sensor 32 is not limited to the shape of a plate, and it may instead or additionally be constituted by a coiled cable or a coiled copper single wire, etc. In one example, the sensor 32 is disposed inside the electron lens barrel 11 and near and above the electron gun 111. The sensor 32 is not limited to such an arrangement but may be disposed at any location within the housing of the electron beam drawing apparatus 1 as long as it does not interfere with the path of the electron beam 110.

The signal processing unit 33 is, for example, an oscilloscope, and is electrically connected to the sensor 32 so as to acquire signals associated with the sensor 32.

The description will assume an exemplary configuration where the signal processing unit 33 is an oscilloscope, but the signal processing unit 33 may instead or additionally be an ammeter, a voltmeter, or the like. For example, the signal processing unit 33 acquires analog data of a current occurring based on the potential of the sensor 32, subjects the analog data to analog-digital conversion, and stores the resultant data (which may also be called “voltage data” below) in the storage unit 34. The voltage data here indicates, for example, a relationship between the potential of the sensor 32 and time.

The discharge detection control unit 31 reads the voltage data stored in the storage unit 34 and performs, based on the read voltage data, discharge detection processing for detecting a variation in the electric field caused by a discharge. The discharge detection control unit 31 then stores the result of this processing in the storage unit 34. This processing result stored in the storage unit 34 is presented, for example, through the monitor 35. The monitor 35 may instead or additionally display the potential-and-time relationship indicated by the voltage data stored in the storage unit 34. It is also possible for the discharge detection processing to be conducted based on the display presentation on the monitor 35.

### (2) Discharge Detection Apparatus

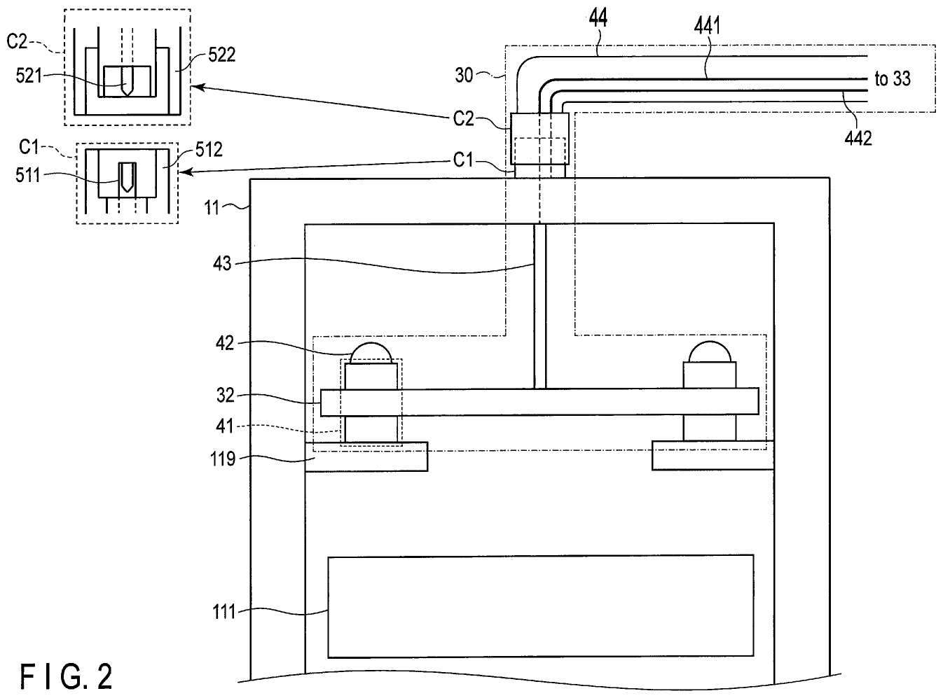

FIG. 2 is a configuration view schematically showing an exemplary configuration of the discharge detecting unit 30 of the electron beam drawing apparatus 1 according to the first embodiment. A description will be given of a retaining member for retaining the sensor 32, by referring to an insulating bushing as a non-limiting example of the same. The techniques that will be discussed below in relation to the insulating bushing are also applicable to other types of retaining members which are adapted to be disposed between two conductive members so as to secure one conductive member to the other conductive member while insulating them from one another. Such retaining members include, for example, a component known as a “feedthrough”.

In one example, the electron lens barrel 11 is provided with one or more installation members 119 arranged in contact with its inner wall. Each installation member 119 is disposed, for example, above the electron gun 111. The sensor 32 is fixed to the installation member 119 through an insulating bushing 41 and a screw 42. In one example, the sensor 32 is fixed in this manner to the multiple installation members 119 arranged inside the electron lens barrel 11 so that it is retained within the electron lens barrel 11 serving as a vacuum container. The insulating bushing 41, or the combination of the insulating bushing 41 and the sensor 32, may be called an antenna retainer. Note that the antenna retainer is not limited to these components but may include other components.

In one example, the sensor 32 is connected to a cable 43. The cable 43 is made of, for example, a conductor. The cable 43 is insulated from the electron lens barrel 11 and connected to a connector C1 provided at the electron lens barrel 11. The connector C1 is coupled with a connector C2 outside the electron beam drawing apparatus 1, and this connector C2 is connected to a cable 44. The cable 44 is connected to the signal processing unit 33. In one example, the connectors C1 and C2 are used for transmitting signals captured inside the electron lens barrel 11 to the outside of the electron beam drawing apparatus 1. The cable 44 is, for example, a coaxial cable. When the cable 44 is a coaxial cable, the connectors C1 and C2 may each be a coaxial connector, examples of which include a BNC connector, a 7/16 DIN connector, an F connector, and so on. The description will assume the cable 44 to be a coaxial cable and each of the connectors C1 and C2 to be a coaxial connector.

In the description below, configurations of the cable 44 and the connectors C1 and C2 will be described first, followed by descriptions related to transmission of signals acquired by the signal processing unit 33.

The cable 44 includes conductors 441 and 442. The conductor 441 is an inner conductor, i.e., a core wire, of the coaxial cable. In the coaxial cable, the conductor 442 is an outer conductor provided around the core wire via an insulator, and functions as, for example, an electromagnetic shield. For the sake of simplified illustration, FIG. 2 shows the conductor 442 with a single solid line.

The connector C1 includes, for example, a first terminal 511 used for electrical connection with the inner conductor of the coaxial cable, and a second terminal 512 insulated from the first terminal 511 and used for electrical connection with the outer conductor of the coaxial cable.

The connector C2 includes, for example, a first terminal 521 used for electrical connection with the inner conductor of the coaxial cable, and a second terminal 522 insulated from the first terminal 521 and used for electrical connection with the outer conductor of the coaxial cable.

A more detailed description will be given in relation to transmission of signals acquired by the signal processing unit 33.

The cable 43 connected with the sensor 32 is electrically connected to the first terminal 511 of the connector C1 while being insulated from the electron lens barrel 11. The first terminal 511 is connected to the first terminal 521 of the connector C2 while being insulated from the electron lens barrel 11. The first terminal 521 is electrically connected to the conductor 441 in the cable 44. The conductor 441 is connected to the signal processing unit 33. As such, the sensor 32 is electrically connected to the signal processing unit 33 via the cable 43, the first terminal 511 of the connector C1, the first terminal 521 of the connector C2, and the conductor 441 in the cable 44, while being insulated from the electron lens barrel 11. In FIG. 2, the state of the cable 43 electrically connected to the conductor 441 is shown by a broken line. The cable 43, the first terminal 511 of the connector C1, the first terminal 521 of the connector C2, and the conductor 441 serve as a transmission path for the signals associated with the sensor 32. The signals reflect, for example, signals captured by the sensor 32. The signal processing unit 33 acquires the signals associated with the sensor 32 through such a transmission path.

On the other hand, the electron lens barrel 11 is electrically connected to the second terminal 512 of the connector C1. The second terminal 512 is connected to the second terminal 522 of the connector C2. The second terminal 522 is electrically connected to the conductor 442 in the cable 44. The conductor 442 is also connected to the signal processing unit 33. The electron lens barrel 11 is therefore electrically connected to the signal processing unit 33 via the second terminal 512 of the connector C1, the second terminal 522 of the connector C2, and the conductor 442 in the cable 44. In FIG. 2, the state of electron lens barrel 11 electrically connected to the conductor 442 is shown by another broken line. The second terminal 512 of the connector C1, the second terminal 522 of the connector C2, and the conductor 442 serve as a transmission path for signals associated with the electron lens barrel 11 being at, for example, the ground potential. The signal processing unit 33 acquires the signals associated with electron lens barrel 11 through such a transmission path.

The signal processing unit 33 generates the aforementioned voltage data indicating the relationship between the potential of the sensor 32 and time, based on the voltage of the sensor 32 obtained from the signal associated with the sensor 32 and using, as a reference potential, the voltage of the electron lens barrel 11 obtained from the signal associated with the electron lens barrel 11. That is, the signal processing unit 33 generates the voltage data from the difference in potential between the set of the first terminals 511 and 521 and the set of the second terminals 512 and 522.

Reasons for the signal processing unit 33 to use the voltage of the electron lens barrel 11 as a reference potential in the above manner include, for example, the following.

Charging and discharging of a discharge source, as well as beam variations due to discharges, take place with respect to the voltage of the electron lens barrel 11. Supposing that the signal processing unit 33 uses, as a reference potential, a voltage other than the voltage of the electron lens barrel 11, the voltage data discussed above would involve a difference between this voltage and the voltage of the electron lens barrel 11, in addition to the intended discharge noise. Also, such voltage data could hamper the observation of high-frequency components of its waveforms. In order to conduct the discharge detection without these issues, how the voltage used as a reference potential is varied with respect to the voltage of the electron lens barrel 11 needs to be taken into consideration. This is substantially synonymous with adopting the voltage of the electron lens barrel 11 as a reference potential. For such reasons, the signal processing unit 33 uses the voltage of the electron lens barrel 11 as a reference potential.

The description will assume that the discharge detecting unit 30 includes the insulating bushing 41, the screw 42, the cable 43, the connectors C1 and C2, and the cable 44. It has been mentioned above that the discharge detecting unit 30 may also be referred to as a discharge detection apparatus. This discharge detection apparatus may include a vacuum container similar to the electron lens barrel 11.

While FIG. 2 illustrates that the connector C1 is provided at the outer wall of the electron lens barrel 11, the embodiment is not limited to such a form. For example, a cable extending from the outer wall of the electron lens barrel 11 to the outside of the electron beam drawing apparatus 1 may be provided so that the connector C1 is arranged at the end of this cable.

The description has assumed the use of a coaxial cable and coaxial connectors for transmission of signals to the signal processing unit 33, but the embodiment is not limited to such a form.

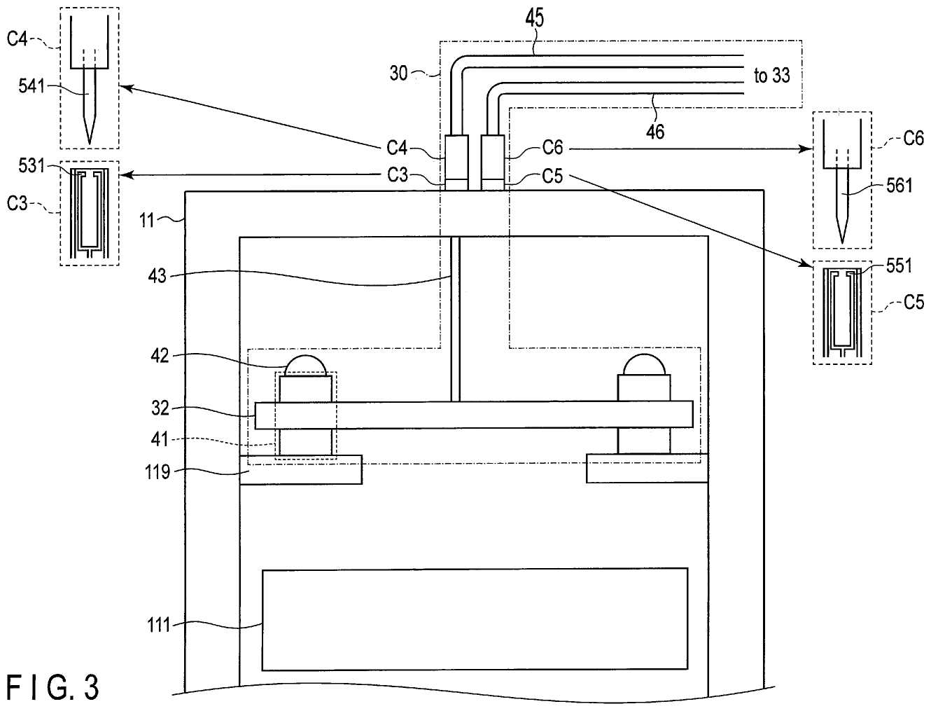

For example, two non-coaxial cables may be used for connecting the sensor 32 and the electron lens barrel 11 to the signal processing unit 33, respectively. In this case, the connections may be established using two physically discrete pairs of connectors, namely, a pair of connectors C3 and C4 and another pair of connectors C5 and C6, in place of one pair of connectors constituted by the connectors C1 and C2. FIG. 3 is a configuration view schematically showing an exemplary configuration of the discharge detecting unit 30 of this case, in the electron beam drawing apparatus 1 according to the first embodiment. The description will basically concentrate on portions different from the portions already described by referring to FIG. 2.

The cable 43 is insulated from the electron lens barrel 11 and is connected to the connector C3 provided at the electron lens barrel 11. This connection creates an electrical connection between the conductor in the cable 43 and a terminal 531 of the connector C3. The connector C3 is connected with the connector C4 outside the electron lens barrel 11, and this connector C4 is connected to a cable 45. With this coupling, the terminal 531 of the connector C3 is connected to a terminal 541 of the connector C4. The terminal 541 is electrically connected to the conductor in the cable 45. The cable 45 is connected to the signal processing unit 33. As such, the sensor 32 is electrically connected to the signal processing unit 33 via the cable 43, the connectors C3 and C4, and the cable 45, while being insulated from the electron lens barrel 11.

On the other hand, the electron lens barrel 11 is electrically connected to a terminal 551 of the connector C5 provided at the electron lens barrel 11. The connector C5 is connected with the connector C6 outside the electron lens barrel 11, and this connector C6 is connected to a cable 46. With this connection, the terminal 551 of the connector C5 is connected to a terminal 561 of the connector C6. The terminal 561 is electrically connected to the conductor in the cable 46. The cable 46 is also connected to the signal processing unit 33. As such, the electron lens barrel 11 is electrically connected to the signal processing unit 33 via the connectors C5 and C6, and the cable 46.

As described above, the discharge detecting unit 30 may include the connectors C3, C4, C5, and C6, and the cables 45 and 46, in place of the connectors C1 and C2, and the cable 44.

Note that in relation to the example assumed by FIG. 3, where the sensor 32 and the electron lens barrel 11 are connected to the signal processing unit 33 via the respective two non-coaxial cables, it is preferable that when two cables are used, such cables are each constituted by a coaxially shielded cable for attaining increased noise tolerance and high-speed signal transmission.

The discharge detecting unit 30 of the electron beam drawing apparatus 1 according to the first embodiment is not limited to the foregoing configuration. The sensor 32 may be electrically connected to the signal processing unit 33 by means of a metal needle contacting the sensor 32 and penetrating through the wall of the electron lens barrel 11, and a type of a cable connectable with the metal needle via, for example, a connector outside the electron lens barrel 11. When such a metal needle is used, the sensor 32 may instead be electrically connected to the signal processing unit 33 by means of a terminal of a BNC connector or the like, which establishes connection between the metal needle and the signal processing unit 33 without an intervening cable.

In the manner as discussed, the sensor 32 and the signal processing unit 33 are electrically connected to each other via a type of a terminal or the like, so that the signal processing unit 33 can acquire signals associated with the sensor 32. Further, the electron lens barrel 11 and the signal processing unit 33 are also electrically connected to each other via some type of a terminal or the like, so that the signal processing unit 33 can acquire signals associated with the electron lens barrel 11. The terminals, etc., employed here may suitably include, similar to a contact point between, for example, the sensor 32 and the cable 43, a portion for forming a connection via a conductive adhesive, conductive epoxy, or the like, or a portion for enabling direct attachment.

### (3) Insulating Bushing

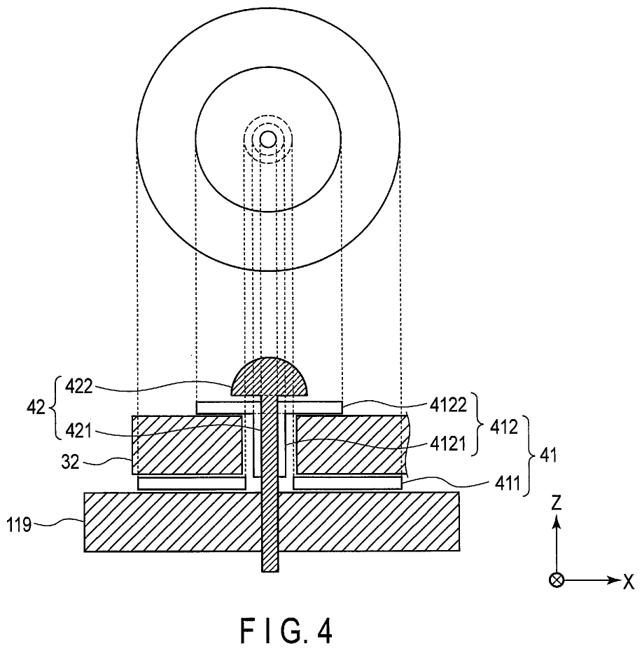

FIG. 4 shows, at its lower part, an exemplary sectional structure of the insulating bushing 41 used for the above described fixation, which is a cut plane orthogonal to the Y direction. FIG. 4 also includes the sectional structures of other components related to the insulating bushing 41. The upper part of FIG. 4 is a plan view of the insulating bushing 41, showing the structure thereof viewed from above.

The insulating bushing 41 includes a first bushing 411 and a second bushing 412.

In one example, the installation member 119 and the electron lens barrel 11 are conductors. The installation member 119 and the electron lens barrel 11 each have a potential corresponding to, for example, a ground potential. The first bushing 411 is disposed on the top surface of the installation member 119. In one example, the first bushing 411 extends in the X and Y directions and has a shape of, when viewed from above, a disc with a circular opening at the center.

The sensor 32 is disposed on the top surface of the first bushing 411. The sensor 32 also includes an opening which is circular when viewed from above. The opening of the first bushing 411 and the opening of the sensor 32 at least partially overlap each other.

The second bushing 412 includes a cylinder part 4121 and a disc part 4122. Note that such partitioning and naming are only for convenience. The cylinder part 4121 has a cylindrical shape including two annular surfaces parallel to the X and Y directions, i.e., the bottom surface and the top surface, and extending in the Z direction. In one example, supposing that the cylinder part 4121 is cut along a plane parallel to the X and Y directions, the resultant sectional plane of the cylinder part 4121 has an outer diameter smaller than the diameter of the opening of the first bushing 411; however, this is not an absolute requirement. The disc part 4122 is disposed on the top surface of the cylinder part 4121. In one example, the disc part 4122 extends in the X and Y directions and has a shape of a disc when viewed from above. In one example, the cylinder part 4121 and the disc part 4122 are concentric when viewed from above. In one example, the second bushing 412 has an opening which, when viewed from above, is circular and penetrates through the respective centers of the cylinder part 4121 and the disc part 4122 in the Z direction. The plan view in FIG. 4 shows an example where the cylinder part 4121, the disc part 4122, and the first bushing 411 are concentric with one another.

For example, the cylinder part 4121 is inserted into the opening of the sensor 32 so that the top surface of the sensor 32 is in contact with the bottom surface of the disc part 4122.

In one example, the screw 42 is a conductor and includes a threaded part 421 and a head 422. In one example, the installation member 119 is provided with an opening having a structure to function as an internal screw for the threaded part 421, i.e., an external screw, to be engaged with. The screw 42 is inserted into the second bushing 412 from above such that the threaded part 421 runs through the opening of the second bushing 412. The threaded part 421 passes through the opening of the first bushing 411 and reaches the opening of the installation member 119 so as to be engaged with this opening of the installation member 119. The head 422 contacts the top surface of the disc part 4122. In this manner, the sensor 32 is fixed to the installation member 119. The screw may have any form as long as it can fix the sensor 32 with respect to the installation member 119. In one example, the screw includes threaded part 421, but does not include the head 421.

The sensor 32 does not contact the installation member 119. The first bushing 411 is disposed between the sensor 32 and the installation member 119. The sensor 32 does not contact the screw 42. The second bushing 412 is disposed between the sensor 32 and the screw 42.

A description has been given of an exemplary configuration of the insulating bushing 41, but the insulating bushing 41 is not limited to the described configuration. For example, the insulating bushing 41 may have a shape different from the shape described above.

A further description of the configurations of the first bushing 411 and the second bushing 412 will be given.

The first bushing 411 and the second bushing 412 each have a given degree of insulating properties that does not affect the discharge detection performed with the discharge detecting unit 30. For example, electrical conductivity of each of the first bushing 411 and the second bushing 412 is such that the number of electrons traveling between the set of the electron lens barrel 11 and the installation member 119, and the sensor 32, via the insulating bushing 41 during the discharge detection is so small that it can be regarded as having no effect on the variation in potential of the sensor 32. Further, the electrical conductivity of each of the first bushing 411 and the second bushing 412 is of a sufficiently large value as to permit the electrons caught by the respective bushings to depart from said bushings before a sufficient number of electrons to trigger a discharge are accumulated there.

To this end, the first bushing 411 and the second bushing 412 are each constituted by, for example, a substance having a specific resistance in the range of from 1×10⁴ to 1×10¹² (Ω·cm) (hereinafter, such a substance may also be called a “resistor” for the sake of description). More preferably, the first bushing 411 and the second bushing 412 are each constituted by, for example, a substance having a specific resistance in the range of from 1×10⁵ to 1×10¹¹ (Ω·cm). Note that these ranges of the specific resistance assume values at room temperature. However, if the insulating bushing 41 is arranged at a location different from that shown in FIG. 2, and this location could become hot, the ranges of the specific resistance above may be adjusted in view of the temperature at the location. Examples of the resistor that may be used for the first bushing 411 and/or the second bushing 412 will be described.

The first bushing 411 is, for example, any one of silicon carbide (SiC), tungsten (W), carbon (C), phosphorus (P), and gold (Au). The first bushing 411 may be made from a paper material. The first bushing 411 may be any combination of such chemical substances. The first bushing 411 may also contain other substances as long as the physical properties of the first bushing 411 for the above described electrical conductivity are not affected.

The first bushing 411 contains one or more of the resistors above. In other examples, the first bushing 411 consists substantially of the one or more resistors. The expression “consists substantially of” is used here to allow for instances where the first bushing 411 does not consist only of the resistor or resistors strictly, but contains impurities that might be inevitably contained when it is manufactured with the intention of consisting only of the resistor or resistors. The first bushing 411 may have a structure including an insulator and a resistor covering the insulator.

The description has been given in connection with the first bushing 411 as an example, and the same description is applicable to the second bushing 412.

Preferably, the insulating bushing 41 as a whole has a resistance substantially comparable with, for example, the characteristic impedance of the cable 43, as well as the characteristic impedance of the cable 44. In one example, the insulating bushing 41 is provided in such a manner that the resistance of the insulating bushing 41 as a whole meets such conditions. Note that the resistance of the insulating bushing 41 as a whole may instead be read as the resistance of a whole set of the insulating bushing 41 and the sensor 32. The resistance of the insulating bushing 41 as a whole can be obtained from, for example, the difference in potential between the sensor 32 and the installation member 119, and the current flowing through the installation member 119. The resistance is likewise also obtainable in cases where the change of reading as above is done. Note that the expression “substantially comparable” is used to allow for instances where the resistance is not strictly equal to the impedance, but an error is involved which may be inevitably caused when production or manufacturing occurs with the intention of there being an equivalence between the resistance and the impedance. The same applies to the following similar expressions. The resistance of the sensor 32 is assumed to be so small as to permit an interpretation in which the resistance of, for example, the whole set of the insulating bushing 41 and the sensor 32 is substantially equal to the resistance of the insulating bushing 41 as a whole.

### Exemplary Operation

An operation performed by the electron beam drawing apparatus 1 for the detection of discharges will be described. The operation proceeds during, for example, the drawing on the sample 20 performed with the electron beam 110.

In one example, the discharge detection control unit 31, while the drawing is ongoing, constantly reads the voltage data stored in the storage unit 34 at given time intervals to determine whether or not a discharge near the sensor 32 is detected based on the read voltage data. This will be described in more detail. The discharge detection control unit 31 determines that a discharge near the sensor 32 has been detected if a condition is met, for example, if the difference between the maximum value and the minimum value of the potential of the sensor 32 within a given period exceeds a threshold. If the condition is not met, the discharge detection control unit 31 determines that the discharge is not detected. As another example, the discharge detection control unit 31 may determine whether or not a discharge is detected based on the analysis of a high-frequency component of the variation in potential of the sensor 32. While the description assumes here that the discharge detection processing is performed during the drawing, the discharge detection control unit 31 may perform such discharge detection processing, for example, after the drawing and based on the voltage data indicating the relationship between the potential of the sensor 32 and the time that spans the drawing period.

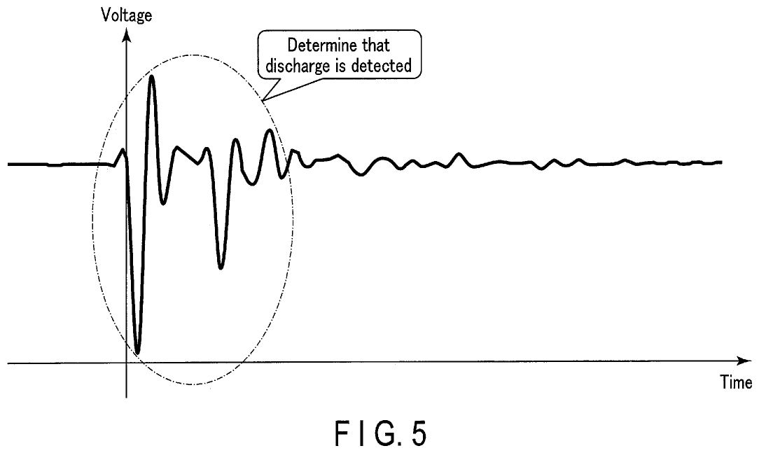

FIG. 5 is an exemplary graph on which the voltage data is plotted. In this graph, the horizontal axis corresponds to time and the vertical axis corresponds to the potential of the sensor 32. The voltage data plotted on the graph meets the aforementioned condition for the portion, for example, enclosed by the dashed circle. Accordingly, the discharge detection control unit 31 determines that a discharge has been detected for the portion enclosed by the dashed circle.

### Advantageous Effects

As an example, a description will be given of the advantageous effects attained by the configuration with the insulating bushing 41; however, the same description can be applied to the instances where the above described resistors are employed for other types of retaining members different from the insulating bushing.

According to a comparative example of the first embodiment, an electron beam drawing apparatus has a configuration corresponding to the electron beam drawing apparatus 1 but replacing the insulating bushing 41 with another insulating bushing. For example, let us suppose that this insulating bushing is constituted by a substance having a specific resistance of 1×10¹³ (Ω·cm) or greater.

In the electronic beam drawing apparatus, such an insulating bushing may be charged by scattered electrons from the electron beam. Since a substance having this level of specific resistance is used as the insulating bushing, electrons caught by the insulating bushing cannot move. As such, the number of electrons caught by the insulating bushing is gradually increased, which eventually causes the insulating bushing to discharge.

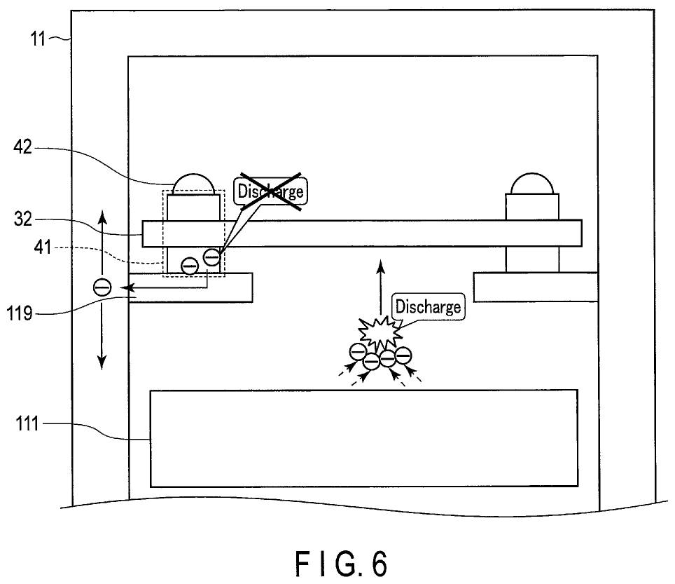

FIG. 6 is a diagram for schematically illustrating movements of electrons caught by the insulating bushing 41 of the electron beam drawing apparatus 1 according to the first embodiment.

The electrons caught by the insulating bushing 41 are permitted to move to the installation member 119 before the insulating bushing 41 accumulates a number of electrons that could trigger a discharge from the insulating bushing 41. The electrons moved to the installation member 119 move to the electron lens barrel 11. Such movements are possible since the resistors as described above are used as the insulating bushing 41. Therefore, even in the state of being charged by scattered electrons from the electron beam 110, the frequency of discharges from the insulating bushing 41 is significantly lower than the frequency of discharges from the insulating bushing according to the comparative example.

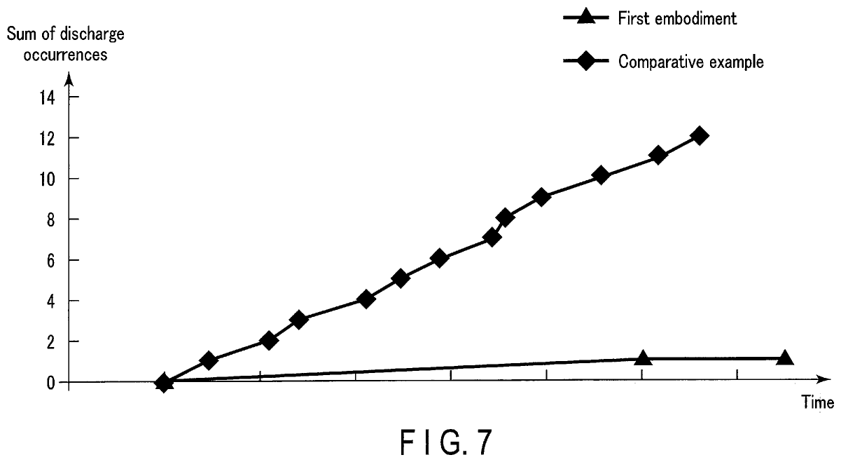

FIG. 7 is an exemplary graph on which a sum of the number of discharges detected by the discharge detecting unit 30 of the electron beam drawing apparatus 1 according to the first embodiment is plotted with respect to a time axis. In this graph, the horizontal axis indicates time and the vertical axis indicates the sum of the number of detected discharges. The graph shows, for illustrative purposes, the state of discharge detection under the conditions that insulating components near the sensor 32 have been removed and also that the best efforts have been made to eliminate the presence of any unintended insulating objects. For comparison, the graph of FIG. 7 similarly plots an example of a sum of the number of discharges detected under substantially the same conditions by the discharge detecting unit of the electron beam drawing apparatus according to the comparative example of the first embodiment.

As shown in FIG. 7, for the same period of time where the comparative example has detected twelve discharges, the electron beam drawing apparatus 1 according to the first embodiment has detected only one discharge. Such a large difference in number of detected discharge occurrences is attributable to the difference between the insulating bushing of the comparative example and the insulating bushing 41 of the electron beam drawing apparatus 1. It can be understood from the example of FIG. 7 that, even if the insulating bushing 41 causes a discharge, the sum of the number of discharges according to the first embodiment has been kept to 1/10 or less than the sum of the number of discharges in the case of using the insulating bushing according to the comparative example.

As described above, in the electron beam drawing apparatus 1 according to the first embodiment, the insulating bushing 41 of the discharge detecting unit 30 discharges significantly less frequently than the insulating bushing according to the comparative example. The electron beam drawing apparatus 1 has a configuration in which this insulating bushing 41 is used for fixation of the sensor 32 within the electron lens barrel 11. Therefore, the electron beam drawing apparatus 1, even including the discharge detecting unit 30, does not substantially increase the discharge occurrences that could result in problems such as an error in drawing patterns. Discharges detected by the discharge detecting unit 30 provided in the above manner can be limited to those due to the insulating objects, etc., present irrespective of the installation of the discharge detecting unit 30. Accordingly, this facilitates the prediction of a part that has caused a discharge to occur, when the discharge is detected by the discharge detecting unit 30. Such high-precision discharge detection processing can also be performed in, for example, instances of arranging the sensor 32 in a region of abundant scattered electrons where a high frequency of discharges is expected, such as a region near the electron gun 111.

Moreover, in the discharge detecting unit 30 of the electron beam drawing apparatus 1 according to the first embodiment, the resistance of the insulating bushing 41 as a whole is substantially comparable with, for example, the characteristic impedance of a signal transmission path for the sensor 32, namely, each of the cables 43 and 44. As such, with the discharge detecting unit 30, waveforms of the signals captured by the sensor 32 are, in a timely and accurate manner, transmitted to the signal processing unit 33. Therefore, the discharge detection processing that includes, based on the voltage data generated by the signal processing unit 33, detecting a variation in the electric field caused by a discharge can be performed with high precision and at high speed.

### Other Embodiments

It has been described for the foregoing embodiment that one or more resistors are used as the insulating bushing employed for fixing the sensor of the discharge detecting unit within the housing of the electron beam drawing apparatus. Likewise, conventional insulating components provided in the electron beam drawing apparatus may also be constituted by such a resistor or resistors. Note that some of these insulating components might be arranged at locations where an occurrence of a leak current from the components would not adversely affect the functions of their neighboring components. To form insulating components arranged at such locations from the resistor(s), the substance used as the resistor(s) may have a specific resistance having a lower limit smaller than that of the above described range. As another option, instead of forming the insulating bushing and/or other insulating components from the resistor(s), a structure of tightly covering the insulating bushing and/or the components using, for example, plates of the resistors, etc. may be adopted.

The description herein uses “connection” or similar expressions with the intention of indicating an electrical connection and does not exclude the forms where, for example, another element or other elements are interposed between the connected elements.

The description herein uses “same”, “coincide”, “constant”, “maintain”, or similar expressions with the intention of covering the cases where a deviation or error occurs within a design range in implementing the technique described for the embodiments. Use of expressions such as “applying a voltage” or “supplying a voltage” is intended to encompass both the meaning of performing a control for applying or supplying the voltage, and the meaning of the voltage being actually applied or supplied. Further, “applying a voltage” or “supplying a voltage” used herein may include instances of applying or supplying, for example, a voltage of 0 V.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit.

In the embodiments described above, descriptions for portions which are not directly required for explaining the present invention, such as detailed configurations of devices and control methods, are omitted. However, it should be noted that the configurations of the devices and the control methods can be suitably selected and used as required. All detection methods and detection apparatuses that comprise the elements of the present invention and that can be suitably modified by a person with ordinary skill in the art are encompassed in the scope of the present invention.

What is claimed is:

1. A discharge detection apparatus comprising:
a vacuum container;
a conductive installation member in the vacuum container, the installation member being connected to the vacuum container so as to be retained by the vacuum container;
a conductive antenna in the vacuum container; and
a retainer comprising a material having a specific resistance of 1×10⁵ to 1×10¹¹ (Ω cm), the retainer retaining the antenna with respect to the installation member without a contact between the installation member and the antenna, by means of a screw located through an inside of the antenna and an inside of the retainer.

2. The discharge detection apparatus according to claim 1, wherein
the retainer comprises:
a first portion including a first opening and located between the installation member and the antenna, and
a second portion including a second opening and located in a third opening formed in the antenna, the second opening extending according to an inner surface of the antenna defined by the third opening, and
the first opening and the second opening are continuous to each other.

3. The discharge detection apparatus according to claim 2, wherein
the antenna comprises a first surface facing the first portion of the retainer and a second surface opposite the first surface, and
the retainer comprises a third portion facing the second surface of the antenna and expanding around the second opening.

4. The discharge detection apparatus according to claim 3, wherein the second portion of the retainer comprises a groove in the second opening, the groove being adapted to be engaged with the screw.

5. The discharge detection apparatus according to claim 4, wherein the second portion of the retainer covers the inner surface of the antenna.

6. The discharge detection apparatus according to claim 5, wherein the installation member comprises, at a surface of the installation member, an opening comprising a groove adapted to be engaged with the screw.

7. The discharge detection apparatus according to claim 1, wherein the retainer consists substantially of the material.

8. The discharge detection apparatus according to claim 1, wherein the retainer further comprises an insulator, the material covering a surface of the insulator.

9. The discharge detection apparatus according to claim 1, further comprising:
a first terminal outside the vacuum container, the first terminal being electrically connected to the antenna and adapted to be connected with a second terminal;
a third terminal outside the vacuum container, the third terminal contacting the vacuum container and being adapted to be connected with a fourth terminal; and
a signal processor electrically connected to the second terminal and the fourth terminal, the signal processor being configured to acquire a potential difference between a potential of the second terminal and a potential of the fourth terminal using the potential of the second terminal as a reference potential.

10. The discharge detection apparatus according to claim 9, wherein the signal processor is further configured to detect an electrical discharge in the vacuum container based on the potential difference.

11. The discharge detection apparatus according to claim 10, wherein the signal processor is further configured to determine that the electrical discharge is detected if the potential difference exceeds a threshold.

12. The discharge detection apparatus according to claim 9, wherein the retainer has a resistance substantially comparable with a characteristic impedance of a signal transmission path between the antenna and the signal processor.

13. A charged particle beam irradiation apparatus comprising:
an electron lens barrel including an electron gun;
a drawing chamber in which drawing is performed to a sample fixed onto a stage, using an electron beam;
an installation member on an inner wall of the electron lens barrel at a region above the electron gun, the installation member being made of conductor;
a first resistor on an upper surface of the installation member, the resistor having a specific resistance of 1×10⁵ to 1×10¹¹ (Ω·cm);
a conductive sensor retained on the first resistor without contacting the installation member;
a first cable connected to the sensor, the first cable including a conductor; and
a signal processor outside the an electron lens barrel, the signal processor configured to receive a signal from the first cable via a connector provided at the electron lens barrel.

14. The charged particle beam irradiation apparatus according to claim 13, wherein the sensor is a metal plate, the metal plate faces the first resistor at a first surface of the sensor, and a second resistor is provided on a second surface of the sensor opposite the first surface.

15. The charged particle beam irradiation apparatus according to claim 13, wherein
the installation member, the first resistor, the second resistor, and the sensor have respective openings, and
the first resistor, the second resistor, and the sensor are retained with respect to the installation member by means of a screw located in the respective openings of the installation member, the first resistor, the second resistor, and the sensor.

16. The charged particle beam irradiation apparatus according to claim 15, further comprising a third resistor in an inside of the opening of the sensor, wherein
the sensor and the screw are insulated from each other by the third resistor.

17. The charged particle beam irradiation apparatus according to claim 13, further comprising:
a second installation member on the inner wall of the electron lens barrel at a region above the electron gun and opposite the region where the installation member is provided, the second installation member being made of conductor; and
a fourth resistor on an upper surface of the second installation member, the fourth resistor having a specific resistance of 1×10⁵ to 1×10¹¹ (Ω·cm), wherein the sensor is retained on the fourth resistor without contacting the second installation member.

18. The charged particle beam irradiation apparatus according to claim 13, wherein
the installation member contacts the electron lens barrel, and
a ground potential provided to the electron lens barrel is provided to the installation member.
